(19) United States
(12) Patent Application Publication
(10) Pub. No.: US 2024/0297025 A1
(43) Pub. Date: Sep. 5, 2024

(54) PLASMA PROCESSING SYSTEM AND PLASMA PROCESSING APPARATUS

(71) Applicant: Tokyo Electron Limited, Tokyo (JP)

(72) Inventors: Kota SENO, Miyagi (JP); Fumiaki ARIYOSHI, Miyagi (JP)

(73) Assignee: Tokyo Electron Limited, Tokyo (JP)

(21) Appl. No.: 18/647,077

(22) Filed: Apr. 26, 2024

Related U.S. Application Data
(63) Continuation of application No. PCT/JP2022/036807, filed on Sep. 30, 2022.

(30) Foreign Application Priority Data
Oct. 29, 2021 (JP) 2021-177166

(51) Int. Cl. H01J 37/32

(52) U.S. Cl. CPC H01J 37/32605; H01J 37/32568; H01J 37/3288; H01J 37/32091

(57) ABSTRACT

A plasma processing system includes a plasma processing apparatus and a transfer device. The plasma processing apparatus includes: a plasma processing chamber; a substrate support disposed inside the plasma processing chamber and having a lower electrode; an upper electrode assembly disposed above the substrate support, and having an electrode support and a replaceable upper electrode plate disposed below the electrode support; and a lifter configured to move the replaceable upper electrode plate vertically between an upper position and a lower position inside the plasma processing chamber, and configured to fix the replaceable upper electrode plate to the electrode support when the replaceable upper electrode plate is in the upper position. The transfer device includes: a transfer chamber; and a transfer robot disposed inside the transfer chamber, and configured to transfer the replaceable upper electrode plate between the lower position inside the plasma processing chamber and the transfer chamber.

### CROSS-REFERENCE TO RELATED APPLICATIONS

This application is a bypass continuation application of International Patent Application No. PCT/JP2022/036807 having an international filing date of Sep. 30, 2022 and designating the United States, the international application being based upon and claiming the benefit of priority from Japanese Patent Application No. 2021-177166, filed on Oct. 29, 2021, the entire contents of each are incorporated herein by reference.

### TECHNICAL FIELD

Exemplary embodiments of the present disclosure relate to a plasma processing system, a plasma processing apparatus, and a maintenance method.

### BACKGROUND

A capacitively coupled plasma processing apparatus is used as a type of plasma processing apparatus. The capacitively coupled plasma processing apparatus includes an upper electrode. The upper electrode includes an electrode plate, i.e., a ceiling plate. The ceiling plate partitions an internal space of a chamber from above. The ceiling plate is exposed to a plasma generated inside the chamber.

### PRIOR ART DOCUMENTS

### Patent Documents

Patent Document 1: Japanese Patent Laid-open Publication No. 2012-129356

### SUMMARY

According to one embodiment of the present disclosure, there is provided a plasma processing system. The plasma processing system includes a plasma processing apparatus and a transfer device. The plasma processing apparatus includes a plasma processing chamber, a substrate support, an upper electrode assembly, and a lifter. The substrate support is disposed inside the plasma processing chamber and has a lower electrode. The upper electrode assembly is disposed above the substrate support, and has an electrode support and a replaceable upper electrode plate disposed below the electrode support. The lifter is configured to move the replaceable upper electrode plate vertically between an upper position and a lower position inside the plasma processing chamber. The lifter is configured to fix the replaceable upper electrode plate to the electrode support when the replaceable upper electrode plate is in the upper position. The transfer device includes a transfer chamber and a transfer robot. The transfer robot is disposed inside the transfer chamber, and is configured to transfer the replaceable upper electrode plate between the lower position inside the plasma processing chamber and the transfer chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a plasma processing system according to one exemplary embodiment.

FIG. 2 is a view schematically illustrating a plasma processing apparatus according to one exemplary embodiment.

FIG. 3 is a cross-sectional view of an upper electrode according to one exemplary embodiment.

FIG. 4 is a cross-sectional view illustrating details of an upper electrode according to one exemplary embodiment.

FIG. 5 is a view illustrating a lower surface of a ceiling plate support according to one exemplary embodiment.

FIG. 6 is a view illustrating a plurality of electrodes in an electrostatic adsorber according to one exemplary embodiment.

FIG. 7 is a flowchart illustrating a maintenance method for a plasma processing system according to one exemplary embodiment.

FIG. 8 is a view illustrating a state during replacement of a ceiling plate in the plasma processing system according to one exemplary embodiment.

FIG. 9 is a view illustrating a state during the replacement of the ceiling plate in the plasma processing system according to one exemplary embodiment.

FIG. 10 is a view illustrating a state during the replacement of the ceiling plate in the plasma processing system according to one exemplary embodiment.

FIG. 11 is a view illustrating a state during the replacement of the ceiling plate in the plasma processing system according to one exemplary embodiment.

FIG. 12 is a view illustrating a state during the replacement of the ceiling plate in the plasma processing system according to one exemplary embodiment.

FIG. 13 is a view illustrating a state during the replacement of the ceiling plate in the plasma processing system according to one exemplary embodiment.

FIG. 14 is a view illustrating a state during the replacement of the ceiling plate in the plasma processing system according to one exemplary embodiment.

FIG. 15 is a cross-sectional view of an upper electrode according to another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the drawings. In addition, the same reference numerals will be given to the same or corresponding parts in each drawing.

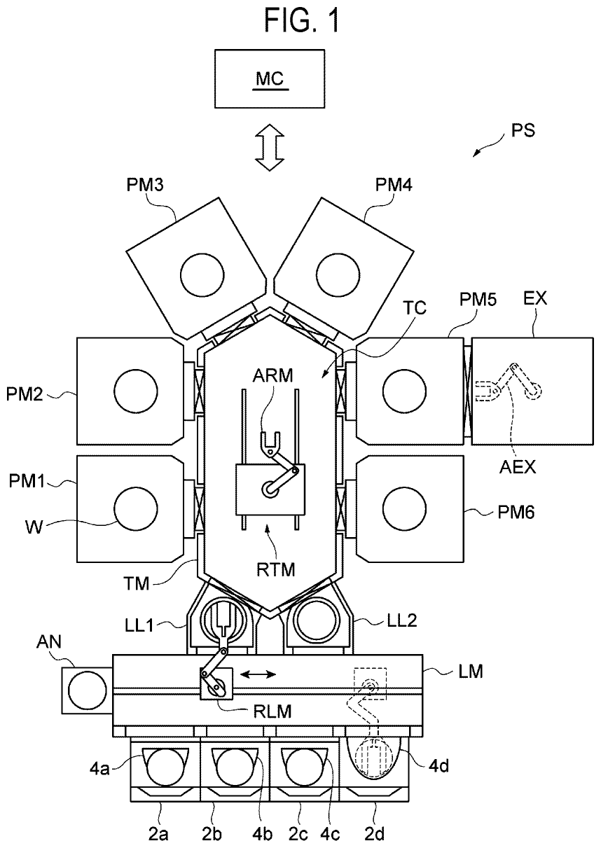

FIG. 1 is a view illustrating a plasma processing system according to one exemplary embodiment. A plasma processing system PS illustrated in FIG. 1 includes process modules PM1 to PM6, a transfer module TM (substrate transfer module), and a controller MC.

The plasma processing system PS may further include stages 2a to 2d, containers 4a to 4d, an aligner AN, load lock modules LL1 and LL2, and an exchange station EX. In addition, the number of stages, the number of containers, and the number of load lock modules in the plasma processing system PS may be any number greater than or equal to one. Further, the number of process modules in the plasma processing system PS may be any number greater than or equal to one.

The stages 2a to 2d are arranged along one rim of a loader module LM. The containers 4a to 4d are mounted on the stages 2a to 2d, respectively. Each of the containers 4a to 4d is, for example, a container referred to as a front opening unified pod (FOUP). Each of the containers 4a to 4d is configured to accommodate a substrate W therein.

The loader module LM has a chamber. An internal pressure of the chamber of the loader module LM is set to atmospheric pressure. The loader module LM has a transfer robot RLM. The transfer robot RLM is controlled by the controller MC. The transfer robot RLM is configured to transfer the substrate W via the chamber of the loader module LM. The transfer robot RLM may transfer the substrate W between each of the containers 4a to 4d and the aligner AN, between the aligner AN and each of the load lock modules LL1 and LL2, and between each of the load lock modules LL1 and LL2 and each of the containers 4a to 4d. The aligner AN is connected to the loader module LM. The aligner AN is configured to perform position adjustment (calibration) of the substrate W.

Each of the load lock modules LL1 and LL2 is provided between the loader module LM and the transfer module TM. Each of the load lock modules LL1 and LL2 provides a preliminary depressurizing chamber. Each of the load lock modules LL1 and LL2 is connected to the loader module LM via a gate valve. Further, each of the load lock modules LL1 and LL2 is connected to the transfer module TM via a gate valve.

The transfer module TM is configured to transfer the substrate under a vacuum environment. The transfer module TM has a depressurizable transfer chamber TC and a transfer robot RTM. The transfer robot RTM has an arm ARM and is controlled by the controller MC. The transfer robot RTM is configured to transfer the substrate W via the transfer chamber TC. The transfer robot RTM may transfer the substrate W between each of the load lock modules LL1 and LL2 and each of the process modules PM1 to PM6 and between any two process modules among the process modules PM1 to PM6.

The transfer module TM may constitute a transfer device according to one embodiment. In this case, the transfer robot RTM may transfer a ceiling plate 34 (replaceable upper electrode plate), which will be described later, to an internal space of a chamber of a process module, which is a plasma processing apparatus. In one embodiment, the transfer robot RTM may be configured to transfer the ceiling plate 34 (replaceable upper electrode plate) between the transfer chamber and a lower position inside a plasma processing chamber of the process module, which is a plasma processing apparatus. The arm ARM of the transfer robot RTM enters a chamber 10, which will be described later, via a sidewall passage 10p of the chamber 10. The ceiling plate 34 is accommodated in a stocker. The stocker may be any of the process modules PM1 to PM6, the containers 4a to 4d, or other modules or additional modules of the plasma processing system.

Each of the process modules PM1 to PM6 is connected to the transfer module TM via a gate valve. Each of the process modules PM1 to PM6 is an apparatus configured to perform dedicated substrate processing. At least one process module among the process modules PM1 to PM6 is a plasma processing apparatus.

The exchange station EX has a chamber (transfer chamber) and a transfer robot. The transfer robot of the exchange station EX has an arm AEX and is controlled by the controller MC. The exchange station EX may be configured to be movable, in order to be connected to a chamber of a process module (e.g., process module PM5), which is a plasma processing apparatus. Further, the exchange station EX is configured such that an internal space of the chamber of the process module, which is a plasma processing apparatus, and an internal space of the chamber of the exchange station EX are connected to each other while these internal spaces are in a depressurized state. The ceiling plate 34 may be transferred by the transfer robot from the chamber of the exchange station EX to the internal space of the chamber of the process module, which is a plasma processing apparatus. In other words, the exchange station EX may be used as another transfer device that transfers the ceiling plate 34 to the internal space of the chamber of the plasma processing apparatus. In one embodiment, the transfer robot of the exchange station EX may be configured to transfer the ceiling plate 34 (replaceable upper electrode plate) between the transfer chamber of the exchange station EX and the lower position inside the plasma processing chamber of the process module, which is a plasma processing apparatus. The arm AEX of the transfer robot of the exchange station EX enters the chamber 10 via the sidewall passage 101p of the chamber 10, which will be described later.

The controller MC is configured to control respective components of the plasma processing system PS. The controller MC may be a computer including a processor, a storage device, an input device, a display device, and the like. The controller MC executes a control program stored in the storage device, thereby controlling respective components of the plasma processing system PS based on recipe data stored in that storage device. A maintenance method according to an exemplary embodiment, which will be described later, may be executed in the plasma processing system PS by controlling respective components of the plasma processing system PS by the controller MC.

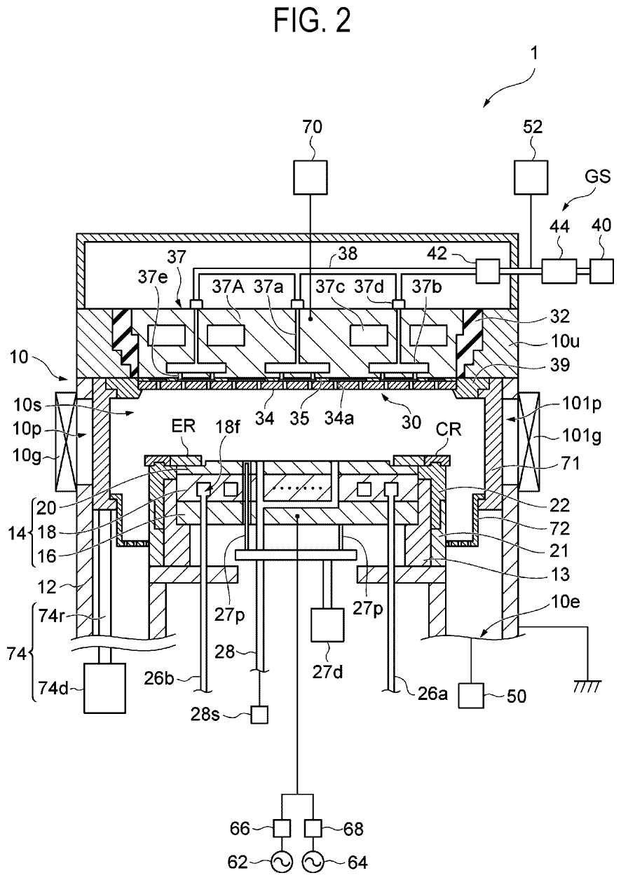

Hereinafter, a plasma processing apparatus according to an exemplary embodiment will be described with reference to FIG. 2. FIG. 2 is a view schematically illustrating a plasma processing apparatus according to one exemplary embodiment. A plasma processing apparatus 1 illustrated in FIG. 2 may be used as one or more process modules of the plasma processing system PS.

The plasma processing apparatus 1 is a capacitively coupled plasma processing apparatus. The plasma processing apparatus 1 includes the chamber 10 (plasma processing chamber). The chamber 10 provides an internal space 10s therein. The chamber 10 may include a chamber main body 12. The chamber main body 12 has a substantially cylindrical shape and provides the internal space 10s therein. The chamber main body 12 is made of aluminum, for example. An inner wall surface of the chamber main body 12 undergoes plasma-resistant processing. For example, the inner wall surface of the chamber main body 12 is anodized. The chamber main body 12 is electrically grounded.

The chamber 10 includes a sidewall. The sidewall provides the passage 10p. The sidewall may be provided by the chamber main body 12. The substrate W passes through the passage 10p when being loaded into the internal space 10s and when being unloaded from the internal space 10s. The passage 10p can be opened and closed by a gate valve 10g. The sidewall of the chamber 10 may also provide a passage 101p. The passage 101p can be opened and closed by a gate valve 101g. The chamber 10 may further include an upper wall 10u. The upper wall 10u is provided on the chamber main body 12 and provides a top opening of the chamber 10.

The plasma processing apparatus 1 further includes a substrate support 14. The substrate support 14 is provided inside the chamber 10. The substrate support 14 includes a base 18 and an electrostatic chuck 20. The substrate support 14 may further include an electrode plate 16.

The substrate support 14 may further include a supporter 13. The supporter 13 is provided on a bottom of the chamber 10. The supporter 13 is made of an insulating material. The supporter 13 has a substantially cylindrical shape. The supporter 13 extends upward in the internal space 10s from the bottom of the chamber 10. The supporter 13 supports the base 18, the electrostatic chuck 20, and the electrode plate 16.

The electrode plate 16 is made of a conductive material such as aluminum and has a substantially disk shape. The base 18 is provided on the electrode plate 16. The base 18 may be made of a conductive material such as aluminum. The base 18 has a substantially disk shape. The base 18 is electrically connected to the electrode plate 16. In one embodiment, the base 18 constitutes a lower electrode of the capacitively coupled plasma processing apparatus. The lower electrode may also be a conductive member in the base 18. Alternatively, the lower electrode may be at least one other electrode provided inside the substrate support 14.

The electrostatic chuck 20 is provided on the base 18. The substrate W is placed on an upper surface of the electrostatic chuck 20. The electrostatic chuck 20 holds the substrate W. The electrostatic chuck 20 has a main body made of a dielectric. A chuck electrode is provided inside the main body of the electrostatic chuck 20. The chuck electrode is a film made of a conductor. The chuck electrode is connected to a direct current (DC) power supply via a switch. When a voltage from the DC power supply is applied to the chuck electrode of the electrostatic chuck 20, electrostatic attraction is generated between the electrostatic chuck 20 and the substrate W. Due to the generated electrostatic attraction, the substrate W is attracted to the electrostatic chuck 20 and is held by the electrostatic chuck 20.

The substrate support 14 may be configured to support an edge ring ER placed thereon. The edge ring ER may be made of silicon, silicon carbide, quartz, or the like. The substrate W is disposed on the substrate support 14 in a region surrounded by the edge ring ER.

The base 18 provides a flow path 18f therein. The flow path 18f receives a coolant supplied from a chiller unit via a pipe 26a. The chiller unit is located outside the chamber 10. The coolant flows through the flow path 18f and is returned to the chiller unit via a pipe 26b.

The plasma processing apparatus 1 may provide a gas supply line 28. The gas supply line 28 supplies a heat transfer gas such as He gas from a heat transfer gas supply mechanism 28s to a gap between the upper surface of the electrostatic chuck 20 and a back surface of the substrate W.

The substrate support 14 may further include an outer peripheral piece 21, an insulator 22, and a covering CR. The outer peripheral piece 21 has a substantially cylindrical shape and is made of a metal such as aluminum. A surface of the outer peripheral piece 21 may be made of a plasma-resistant material. The outer peripheral piece 21 extends along an outer periphery of the supporter 13.

The insulator 22 is provided on the outer peripheral piece 21. The insulator 22 has a substantially cylindrical shape and is made of an insulating material such as silicon oxide. The insulator 22 extends along the outer periphery of the supporter 13 and the electrostatic chuck 20. The covering CR has a substantially annular shape and is made of an insulating material such as silicon oxide. The covering CR is provided on the insulator 22. The edge ring ER is positioned in a region surrounded by the covering CR.

The plasma processing apparatus 1 further includes an upper electrode 30 (upper electrode assembly). The upper electrode 30 is provided above the substrate support 14. The upper electrode 30 includes the ceiling plate 34 (replaceable upper electrode plate) and a support 37 (ceiling plate support or electrode support). The ceiling plate 34 is disposed above the substrate support 14 and below the support 37. The ceiling plate 34 has a substantially disk shape. A lower surface of the ceiling plate 34 faces the internal space 10s and defines the internal space 10s. The ceiling plate 34 may be made of a conductor or semiconductor with a low electrical resistance that generates little Joule heat. The ceiling plate 34 is made of silicon, for example. The ceiling plate 34 provides a plurality of gas holes 34a. The gas holes 34a penetrate the ceiling plate 34 in a thickness direction thereof.

The support 37 is provided inside the top opening of the chamber 10. The support 37 closes the top opening of the chamber 10 in conjunction with a member 32. The member 32 is interposed between the support 37 and the upper wall 10u of the chamber 10 and is made of an insulating material such as silicon oxide.

The support 37 includes a main body 37A (support member) and an electrostatic adsorber 35 (electrostatic adsorption layer). The main body 37A is made of a conductive material such as aluminum. The electrostatic adsorber 35 is attached to the main body 37A. In one embodiment, the electrostatic adsorber 35 is formed on a lower surface of the main body 37A. The electrostatic adsorber 35 holds or electrostatically adsorbs the ceiling plate 34 by generating electrostatic attraction between the ceiling plate 34 and the electrostatic adsorber 35. Details of the electrostatic adsorber 35 will be described later.

The main body 37A provides a flow path 37c therein. The flow path 37c receives a coolant supplied from a chiller unit. The chiller unit is located outside the chamber 10. The coolant flows through the flow path 37c and is returned to the chiller unit. With this configuration, a temperature of the main body 37A is adjusted. In the plasma processing apparatus 1, a temperature of the ceiling plate 34 is adjusted by heat exchange between the main body 37A and the ceiling plate 34.

The main body 37A also provides a plurality of gas introduction paths 37a in an interior thereof. The gas introduction paths 37a are formed to extend downward from an upper surface of the main body 37A to the interior of the main body 37A. The main body 37A also provides a plurality of gas diffusion chambers 37b in the interior thereof. The gas introduction paths 37a are respectively connected to the gas diffusion chambers 37b. The main body 37A also provides a plurality of gas flow paths 37e. Each of the gas flow paths 37e extends from a corresponding one of the gas diffusion chambers 37b toward the lower surface of the main body 37A (or an upper surface of the ceiling plate 34). The gas flow paths 37e supply a processing gas to the gas holes 34a of the ceiling plate 34. The main body 37A also provides a plurality of gas introduction ports 37d. The gas introduction ports 37d are respectively connected to the gas introduction paths 37a. A gas supply pipe 38 is connected to the gas introduction ports 37d.

A gas supply GS is connected to the gas supply pipe 38. In one embodiment, the gas supply GS includes a gas source group 40, a valve group 42, and a flow rate controller group 44. The gas source group 40 is connected to the gas supply pipe 38 via the flow rate controller group 44 and the valve group 42. The gas source group 40 includes a plurality of gas sources. The gas sources include sources of a plurality of gases constituting the processing gas. The valve group 42 includes a plurality of on/off valves. The flow rate controller group 44 includes a plurality of flow rate controllers. Each of the flow rate controllers is a mass flow controller or a pressure-controlled flow rate controller. Each of the gas sources in the gas source group 40 is connected to the gas supply pipe 38 via a corresponding valve in the valve group 42 and a corresponding flow rate controller in the flow rate controller group 44.

The plasma processing apparatus 1 further includes a radio frequency power supply 62 and a bias power supply 64. The radio frequency power supply 62 is configured to generate source radio frequency power for plasma generation. A frequency of the source radio frequency power is, for example, within a range of 27 MHz to 100 MHz. The radio frequency power supply 62 is connected to the lower electrode (e.g., the base 18) via a matcher 66 and the electrode plate 16. The matcher 66 has a matching circuit for matching a load-side input impedance of the radio frequency power supply 62 to an output impedance of the radio frequency power supply 62. In addition, the radio frequency power supply 62 may be connected to the upper electrode 30 via the matcher 66.

The bias power supply 64 is configured to generate electrical bias energy for drawing ions into the substrate W. The electrical bias energy has a frequency lower than the frequency of the source radio frequency power, for example, within a range of 100 kHz to 13.56 MHz. The electrical bias energy is, for example, bias radio frequency power. In this case, the bias power supply 64 is connected to the base 18 via a matcher 68 and the electrode plate 16. The matcher 68 has a matching circuit for matching a load-side input impedance of the bias power supply 64 to an output impedance of the bias power supply 64.

The plasma processing apparatus 1 may further include a DC power source 70. The DC power source 70 is connected to the upper electrode 30. The DC power source 70 is capable of generating a negative DC voltage to apply the DC voltage to the upper electrode 30.

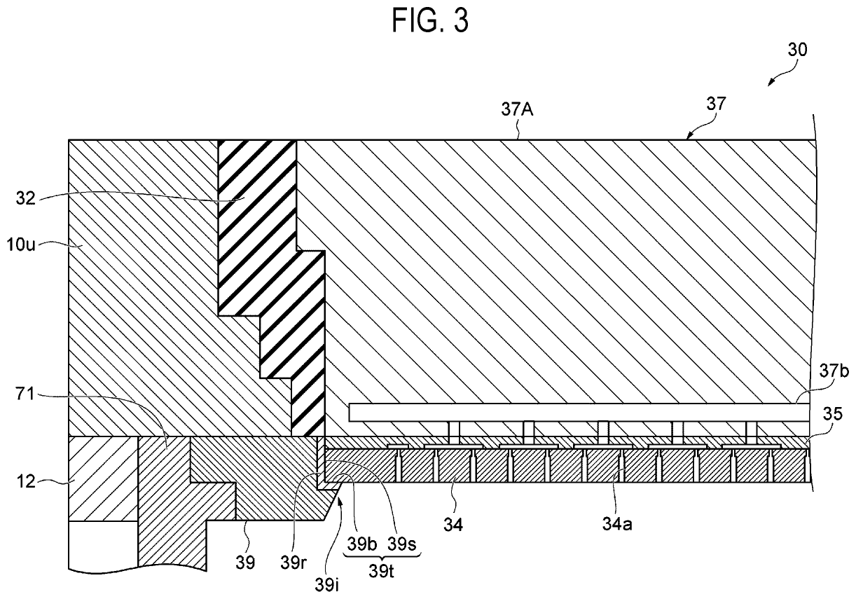

Hereinafter, reference will be made to FIG. 3 together with FIG. 2. FIG. 3 is a cross-sectional view of an upper electrode according to one exemplary embodiment. As illustrated in FIG. 3, the upper electrode 30 has a structure in which the ceiling plate 34 and the support 37 are sequentially stacked from bottom. In the support 37, the electrostatic adsorber 35 is formed integrally with the main body 37A so as to be in contact with the lower surface of the main body 37A. The electrostatic adsorber 35 is formed on the support 37 by, for example, thermal spraying. The electrostatic adsorber 35 is interposed between the ceiling plate 34 and the main body 37A. The ceiling plate 34 is attracted by the electrostatic adsorber 35 so as to be brought into contact with a lower surface of the electrostatic adsorber 35 and is held by the electrostatic adsorber 35. Further, the ceiling plate 34 is electrically connected to the main body 37A.

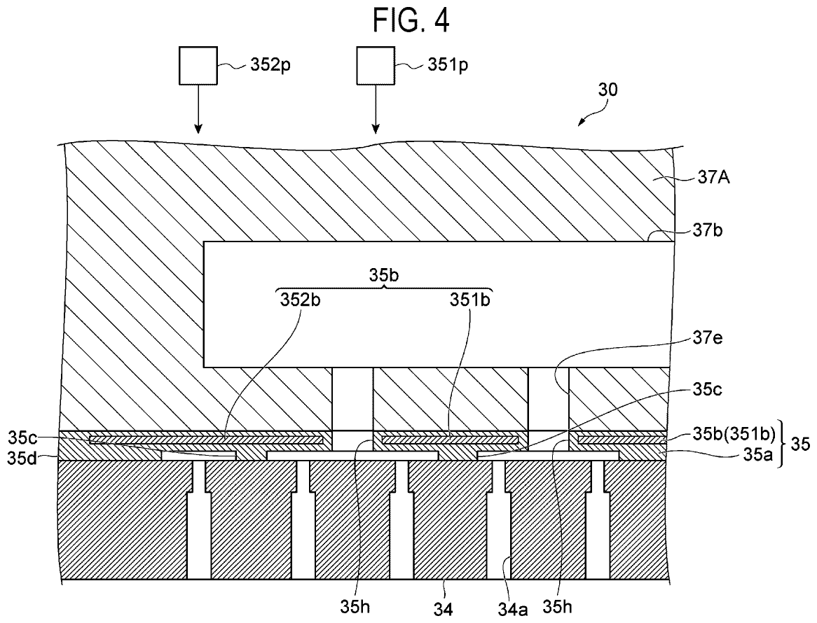

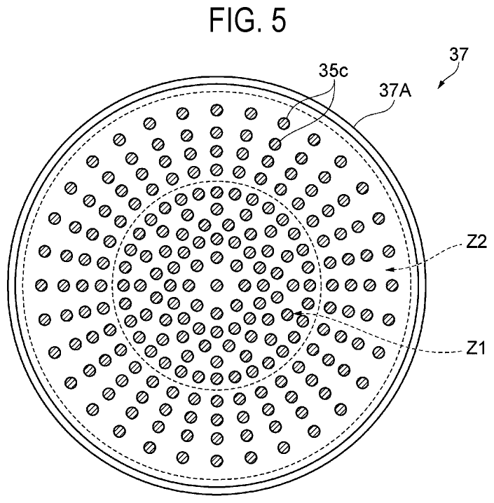

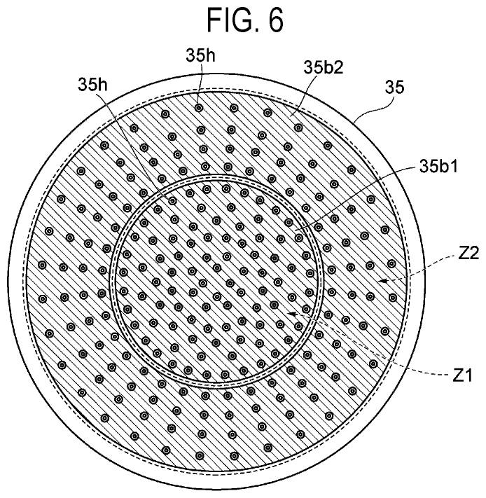

Hereinafter, reference will be made to FIGS. 4 to 6 together with FIGS. 2 and 3. FIG. 4 is a cross-sectional view illustrating details of an upper electrode according to one exemplary embodiment. FIG. 5 is a view illustrating a lower surface of a ceiling plate support according to one exemplary embodiment. FIG. 6 is a view illustrating a plurality of electrodes in an electrostatic adsorber according to one exemplary embodiment. The electrostatic adsorber 35 includes a main body 35a. The main body 35a is made of a dielectric such as alumina (Al₂O₃) or aluminum nitride (AlN). The electrostatic adsorber 35 further includes one or more electrodes 35b. The one or more electrodes 35b are films made of a conductor and are provided inside the main body 35a. The one or more electrodes 35b may include sprayed films formed by thermal spraying, plates made of a conductor, or both. The one or more electrodes 35b are connected to one or more power supplies. When a voltage from the one or more power supplies is applied to the one or more electrodes 35b, electrostatic attraction is generated between the electrostatic adsorber 35 and the ceiling plate 34. Due to the generated electrostatic attraction, the ceiling plate 34 is attracted to the electrostatic adsorber 35 and is held by the electrostatic adsorber 35. In addition, the one or more power supplies connected to the one or more electrodes 35b may be DC power supplies or alternating current (AC) power supplies.

In one embodiment, the electrostatic adsorber 35 includes a plurality of electrodes 35b. The electrodes 35b include a first electrode 351b and a second electrode 352b. The first electrode 351b is provided radially inward with respect to the second electrode 352b. In other words, the first electrode 351b is provided in a central zone Z1 (see FIGS. 5 and 6) of the main body 35a. The second electrode 352b is provided in an outer zone Z2 (see FIGS. 5 and 6) of the main body 35a. A voltage from a power supply 351p and a voltage from a power supply 352p are applied to the first electrode 351b and the second electrode 352b, respectively. Each of the power supplies 351p and 352p may be a DC power supply or an AC power supply. When the voltage from the power supply 351p and the voltage from the power supply 352p are applied to the first electrode 351b and the second electrode 352b, respectively, electrostatic attraction is generated between the electrostatic adsorber 35 and the ceiling plate 34. Due to the generated electrostatic attraction, the ceiling plate 34 is attracted to the electrostatic adsorber 35 and is held by the electrostatic adsorber 35.

In addition, a DC voltage generated by the power supply 351p and a DC voltage generated by the power supply 352p may differ from each other or may be the same. Further, a DC voltage from a single DC power supply may be applied to both the first electrode 351b and the second electrode 352b. Further, the electrostatic adsorber 35 may include only a single electrode as the one or more electrodes 35b.

The electrostatic adsorber 35 provides a plurality of through-holes 35h. The through-holes 35h penetrate the electrostatic adsorber 35 in a thickness direction thereof (vertical direction). The through-holes 35h are respectively aligned with and connected to the gas flow paths 37e of the support 37. The through-holes 35h extend to the lower surface of the electrostatic adsorber 35. The processing gas present in the gas diffusion chambers 37b passes through the gas flow paths 37e and the through-holes 35h of the electrostatic adsorber 35, and is supplied to the upper surface of the ceiling plate 34.

The electrostatic adsorber 35 provides a plurality of protrusions 35c. The protrusions 35c protrude downward. The protrusions 35c constitute a portion of the lower surface of the electrostatic adsorber 35. The electrostatic adsorber 35 is configured such that only tip faces (i.e., adsorption faces) of the protrusions 35c are brought into contact with the upper surface of the ceiling plate 34. The protrusions 35c form a dot pattern, for example. Further, an annular protrusion 35d that surrounds an entirety of the protrusions 35c may be provided around an outermost periphery of the protrusions 35c. In addition, the annular protrusion 35d may be provided at any position in a radial direction of the electrostatic adsorber 35.

The through-holes 35h of the electrostatic adsorber 35 are open between the protrusions 35c. In other words, the through-holes 35h of the electrostatic adsorber 35 and the gas flow paths 37e are arranged so as not to be aligned with the protrusions 35c. The processing gas supplied from the gas flow paths 37e is first collected in a space between the protrusions 35c of the electrostatic adsorber 35 and then discharged from the gas holes 34a to the internal space 10s of the chamber 10. With this structure, it is possible to prevent radicals or gases in the internal space 10s from moving from the gas holes 34a to the gas flow paths 37e of the support 37. Further, it is possible to prevent generation of abnormal discharge in the gas flow paths 37e.

When the ceiling plate 34 is separated from the electrostatic adsorber 35, application of voltage (DC voltage or AC voltage) to the one or more electrodes 35b of the electrostatic adsorber 35 is stopped, and a gas is output from the gas supply GS. The ceiling plate 34 is pushed down in a direction away from the electrostatic adsorber 35 by a pressure of the gas. As a result, the ceiling plate 34 is easily separated from the electrostatic adsorber 35.

In the upper electrode 30 described above, the electrostatic adsorber 35 is formed directly on the lower surface of the main body 37A of the support 37. Thus, heat of the ceiling plate 34 is efficiently conducted to the main body 37A. Therefore, it is possible to cool the ceiling plate 34 efficiently. Further, since the processing gas is supplied to a space between the protrusions 35c, the heat of the ceiling plate 34 is more efficiently transferred to the main body 37A of the support 37. Further, since the protrusions 35c form a dot pattern, the processing gas is uniformly diffused over the entire upper surface of the ceiling plate 34. Accordingly, it becomes possible to cool the entire ceiling plate 34 uniformly.

Reference will again be made to FIG. 2. The plasma processing system PS is configured such that the ceiling plate 34 of the upper electrode 30 of the plasma processing apparatus 1 can be replaced. The ceiling plate 34 is transferred to the internal space 10s by an arm (arm ARM or arm AEX) and is held by the electrostatic adsorber 35.

The ceiling plate 34 is detachably attached with respect to the electrostatic adsorber 35. Further, the ceiling plate 34 is loaded into the chamber 10 by the arm (arm ARM or arm AEX) of the above-described transfer robot and is held by the electrostatic adsorber 35 of the support 37 by electrostatic attraction. Accordingly, the ceiling plate 34 can be replaced easily.

In one embodiment, the plasma processing system PS may further include a lifter (lifter unit). The lifter is configured to lift the ceiling plate 34, which is transferred by the arm (arm ARM or arm AEX), to a position immediately below the support 37. In one embodiment, the lifter is configured to move the ceiling plate 34 vertically between an upper position and a lower position in the chamber 10. The lifter is configured to fix the ceiling plate 34 to the support 37 when the ceiling plate 34 is in the upper position. In addition, in one embodiment, the ceiling plate 34 is transferred by the transfer robot between the lower position in the chamber 10 and the transfer chamber, as described above.

As illustrated in FIGS. 2 and 3, the lifter includes a cylindrical wall structure and an actuator. The cylindrical wall structure is disposed between an inner wall (sidewall) of the chamber 10 and the substrate support 14. The cylindrical wall structure is configured to support the ceiling plate 34. The actuator is configured to move the cylindrical wall structure vertically. In one embodiment, the cylindrical wall structure includes a cylindrical member and an annular member 39. In one example, the cylindrical member is a shutter 71. In one example, the actuator is a shutter drive 74. In other words, the lifter may include the shutter 71, the shutter drive 74, and the annular member 39. The shutter 71 and the annular member 39 are provided radially outward of the substrate support 14. The shutter 71 has a cylindrical shape and is provided inside the chamber 10. The shutter 71 extends along the sidewall of the chamber 10. The shutter 71 is made of a conductor such as aluminum and is grounded. A surface of the shutter 71 may be made of a plasma-resistant material.

The shutter 71 is moved up and down by the shutter drive 74 to open and close the passages 10p and 101p. The shutter drive 74 is provided below the shutter 71. The shutter drive 74 may include a rod 74r and a drive source 74d. The rod 74r is coupled to a lower end of the shutter 71 and extends downward. The rod 74r is connected to the drive source 74d. The drive source 74d generates power to move the shutter 71 up and down via the rod 74r. The drive source 74d may be a motor, or a hydraulic or pneumatic drive source. In addition, the lifter may include a plurality of shutter drives to move the shutter 71 up and down. The plurality of shutter drives may be arranged at equal intervals along a circumferential direction in a region below the shutter 71.

The plasma processing apparatus 1 may further include a baffle member 72. The baffle member 72 extends between the shutter 71 and an outer periphery of the substrate support 14. The baffle member 72 provides a plurality of through-holes via which an upper space and a lower space thereof are in communication with each other. The baffle member 72 is made of a conductor such as aluminum and is grounded. A surface of the baffle member 72 may be made of a plasma-resistant material. An outer edge of the baffle member 72 is fixed to the shutter 71 (e.g., a lower end portion of the shutter 71). An inner edge of the baffle member 72 is disposed to provide a slight gap between the inner edge and the outer periphery of the substrate support 14. An exhaust port 10e is provided below the baffle member 72 and at the bottom of the chamber 10. An exhaust device 50 is connected to the exhaust port 10e. The exhaust device 50 has a pressure control valve and a vacuum pump such as a turbo molecular pump.

The annular member 39 has an annular shape. The annular member 39 is made of a conductive material and is grounded. The annular member 39 may be made of the same material as the ceiling plate 34. The annular member 39 may be made of silicon. The annular member 39 is used to cover a lower surface of the upper wall 10u and a lower surface of the member 32 inside the chamber 10 of the plasma processing apparatus 1.

The annular member 39 extends inward from the cylindrical member, i.e., the shutter 71, and is configured to support the ceiling plate 34. In one embodiment, the annular member 39 is disposed on the shutter 71 and is supported by the shutter 71. In one embodiment, an outer edge of the annular member 39 is disposed on an upper end of the shutter 71. The outer edge of the annular member 39 and the upper end of the shutter 71 may respectively provide stepped surfaces facing each other. The stepped surface of the outer edge of the annular member 39 is disposed on the stepped surface of the upper end of the shutter 71. With this configuration, positioning of the annular member 39 on the shutter 71 is made automatically.

As illustrated in FIG. 3, the annular member 39 includes an inner edge 39i. The inner edge 39i is configured to support the ceiling plate 34 (a peripheral edge of the ceiling plate 34). In one embodiment, the inner edge 39i may provide a stepped surface 39t (inner peripheral stepped surface), and the ceiling plate 34 may be supported by the stepped surface 39t. The stepped surface 39t includes a bottom surface 39b, on which the peripheral edge of the ceiling plate 34 is placed, and an inner peripheral surface 39s facing an end surface of the ceiling plate 34. By the stepped surface 39t, positioning of the ceiling plate 34 on the inner edge 39i of the annular member 39 is made automatically.

In one embodiment, a portion 39r of the inner edge 39i including the stepped surface 39t may be made of an insulating material. In this case, the ceiling plate 34 and the annular member 39 are electrically insulated from each other. In one embodiment, the portion 39r may be an insulator disposed on the stepped surface 39t and constitute a part of a cylindrical wall structure.

In one embodiment, the plasma processing system PS may further include a plurality of lifter pins 27p and a pin drive 27d. The lifter pins 27p are configured to support the ceiling plate 34 at the lower position described above. The lifter pins 27p are configured to be capable of protruding upward from an upper surface of the substrate support 14 and retracting downward from the upper surface of the substrate support 14. The lifter pins 27p are fixed to a link below the substrate support 14. The pin drive 27d is provided below the substrate support 14 and the link. The link is fixed to the pin drive 27d. The pin drive 27d moves the lifter pins 27p upward to receive the ceiling plate 34 transferred by the arm. The pin drive 27d may include a motor or a hydraulic or pneumatic drive source.

The pin drive 27d moves the lifter pins 27p upward to receive the ceiling plate 34, which is transferred by the arm (arm ARM or arm AEX), at an upper end of each of the lifter pins 27p. The shutter drive 74 moves the annular member 39 and the shutter 71 upward after the arm (arm ARM or arm AEX) is retracted from the internal space 10s, so that the annular member 39 receives the ceiling plate 34 from the lifter pins 27p. The lifter pins 27p may be configured to support the substrate W and/or the edge ring ER above the substrate support 14. In one embodiment, the lifter pins 27p may be configured to move the substrate W or the edge ring ER placed on the substrate support 14 up and down over the substrate support 14.

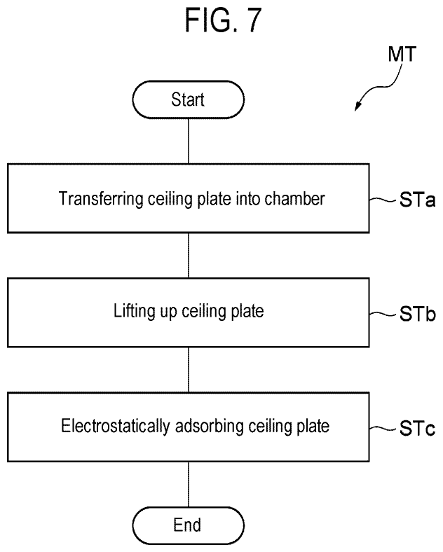

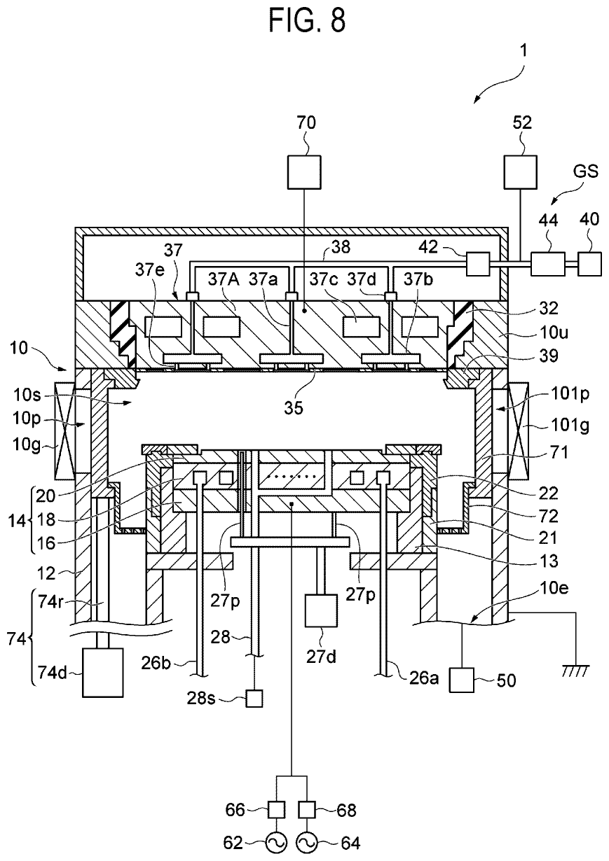

Hereinafter, a maintenance method for the plasma processing system PS and operations of respective components of the plasma processing system PS will be described with reference to FIGS. 7 to 14. FIG. 7 is a flowchart illustrating a maintenance method for a plasma processing system according to one exemplary embodiment. FIGS. 8 to 14 are views each illustrating a state during replacement of a ceiling plate in the plasma processing system according to one exemplary embodiment.

In the maintenance method (hereinafter referred to as “Method MT”) illustrated in FIG. 7, respective components of the plasma processing system PS are controlled by the controller MC. The controller MC may be configured to replace the ceiling plate 34 with another ceiling plate 34 when either an accumulated exposure time of the ceiling plate 34 to plasma generated in the chamber 10 or a consumption amount of the ceiling plate 34 meets a predetermined criterion. The predetermined criterion is met when the accumulated exposure time of the ceiling plate 34 to the plasma generated in the chamber 10 exceeds a predetermined time. Alternatively, the predetermined criterion is met when the consumption amount of the ceiling plate 34 exceeds a predetermined threshold. The consumption amount of the ceiling plate 34 may be measured optically by using, for example, an optical measurement device such as a spectrophotometer.

In Method MT, in order to replace the ceiling plate 34, the ceiling plate 34 is moved by the actuator (shutter drive 74) from the upper position to the lower position as described above. Next, the ceiling plate 34 is unloaded from the lower position inside the chamber 10 to the transfer chamber by the transfer robot (e.g., the arm thereof). To unload the ceiling plate 34, the controller MC controls the lifter (e.g., shutter drive 74) and the above-described transfer robot.

By the above-described control, in Method MT, a state in which the ceiling plate 34 is unloaded by the arm (arm ARM or arm AEX) of the transfer robot, as illustrated in FIG. 8, is caused. Then, a ceiling plate 34 for replacement (e.g., a ceiling plate before use) is loaded into the chamber 10 and installed inside the chamber 10. In loading the ceiling plate 34 for replacement into the chamber 10 and installing the ceiling plate 34 for replacement, the controller MC controls the lifter (e.g., shutter drive 74) and the above-described transfer robot.

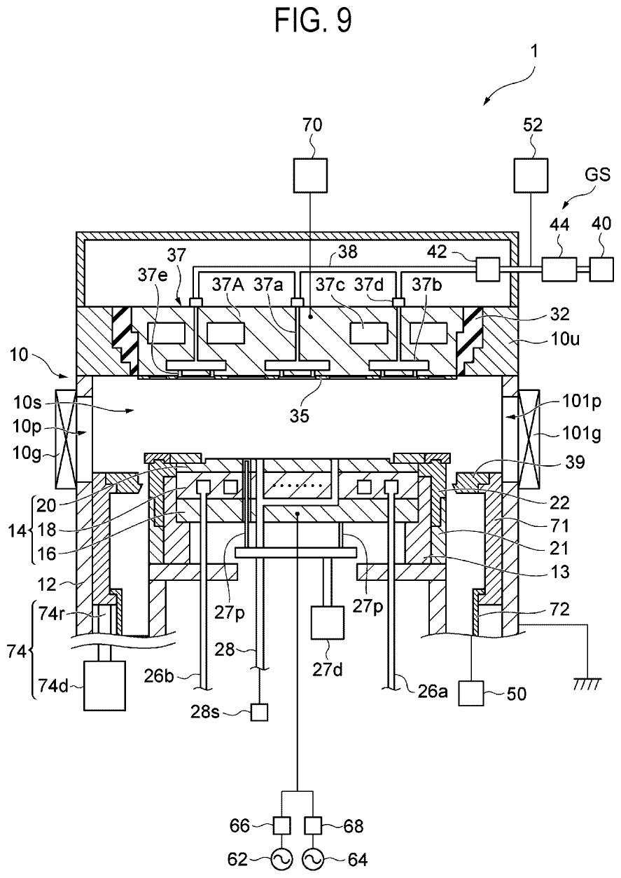

In step STa of Method MT, the ceiling plate 34 for replacement is transferred into the chamber 10 by the arm. In other words, the ceiling plate 34 for replacement is transferred from the transfer chamber to the lower position inside the chamber 10. In one embodiment, first, as illustrated in FIG. 9, the shutter 71 and the annular member 39 are moved to below the upper surface of the substrate support 14 by the shutter drive 74 at a location inside the internal space 10s and outward of the substrate support 14. The shutter drive 74 is controlled by the controller MC.

Subsequently, when the arm ARM is used to transfer the ceiling plate 34, the gate valve 10g is moved to open the passage 10p. The internal space 10s of the chamber 10 and the internal space of the transfer chamber TC of the transfer module TM are maintained in a depressurized state until the passage 10p is closed by the gate valve 10g. In addition, when the arm AEX is used to transfer the ceiling plate 34, the gate valve 101g is moved to open the passage 101p. In this case, the internal space 10s of the chamber 10 and the internal space of the chamber of the exchange station EX are maintained in a depressurized state until the passage 101p is closed by the gate valve 101g.

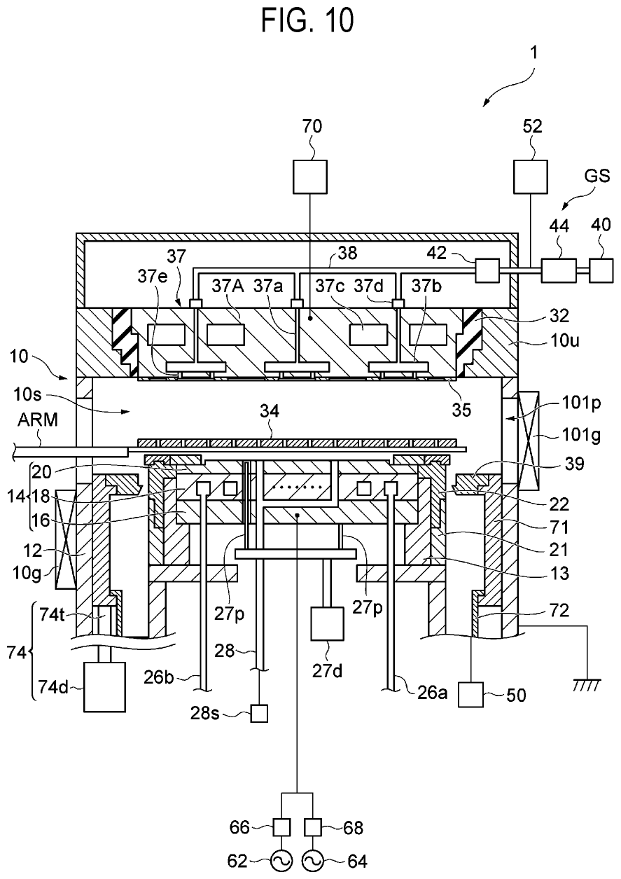

Subsequently, as illustrated in FIG. 10, the transfer robot RTM of the transfer module TM is controlled by the controller MC so that the arm ARM supporting the ceiling plate 34 enters the internal space 10s. In addition, when the arm AEX is used to transfer the ceiling plate 34, the transfer robot of the exchange station is controlled by the controller MC.

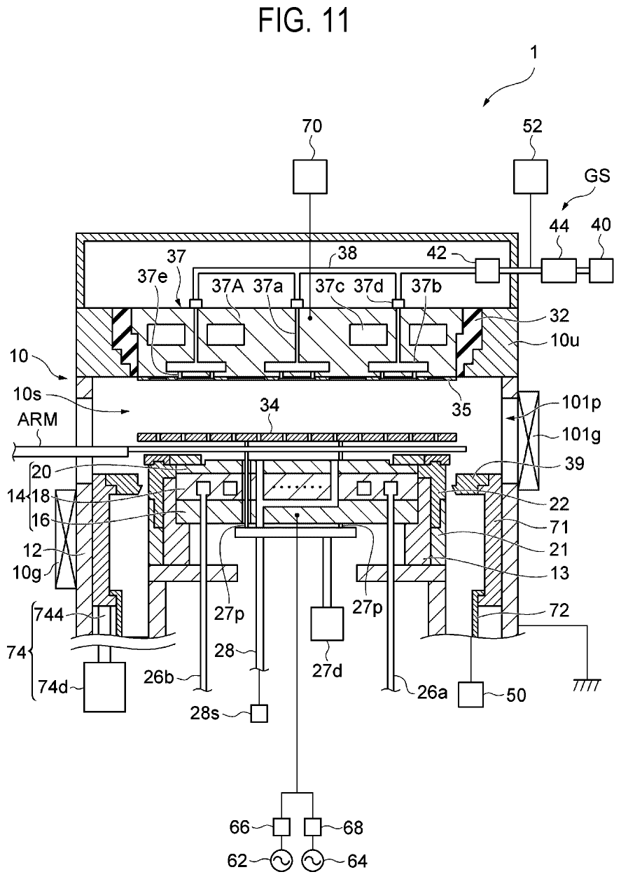

Thereafter, the ceiling plate 34 for replacement is moved from the lower position to the upper position. In other words, in step STb, the ceiling plate 34 is lifted up to immediately below the support 37 (electrostatic adsorber 35). In one embodiment, as illustrated in FIG. 11, the lifter pins 27p are moved upward by the pin drive 27d to receive the ceiling plate 34 on the upper end of each of the lifter pins 27p from the arm (arm ARM or arm AEX). The pin drive 27d is controlled by the controller MC.

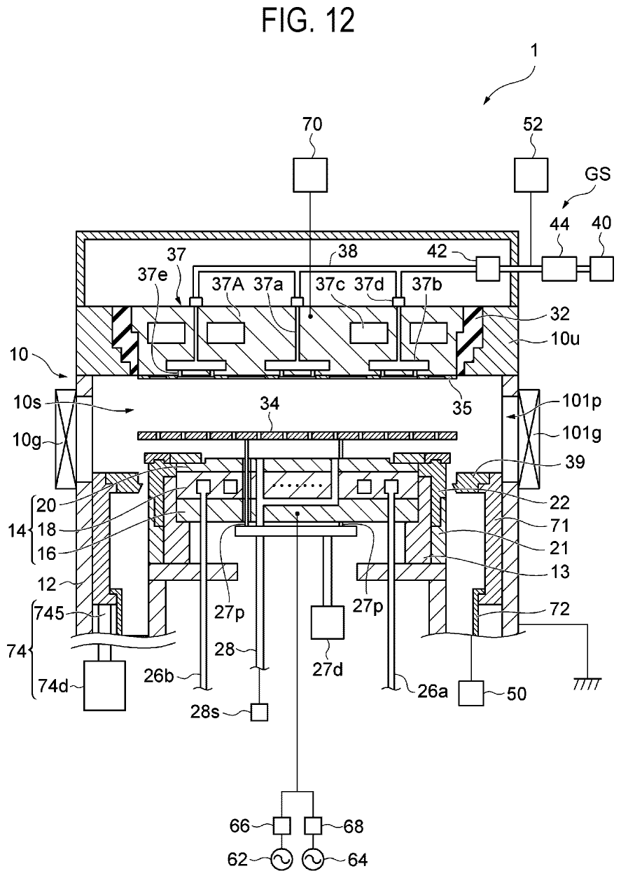

Subsequently, as illustrated in FIG. 12, the arm (arm ARM or arm AEX) is retracted from the internal space 10s. When the arm ARM is used to transfer the ceiling plate 34, the gate valve 10g is moved to close the passage 10p. When the arm AEX is used to transfer the ceiling plate 34, the gate valve 101g is moved to close the passage 101p.

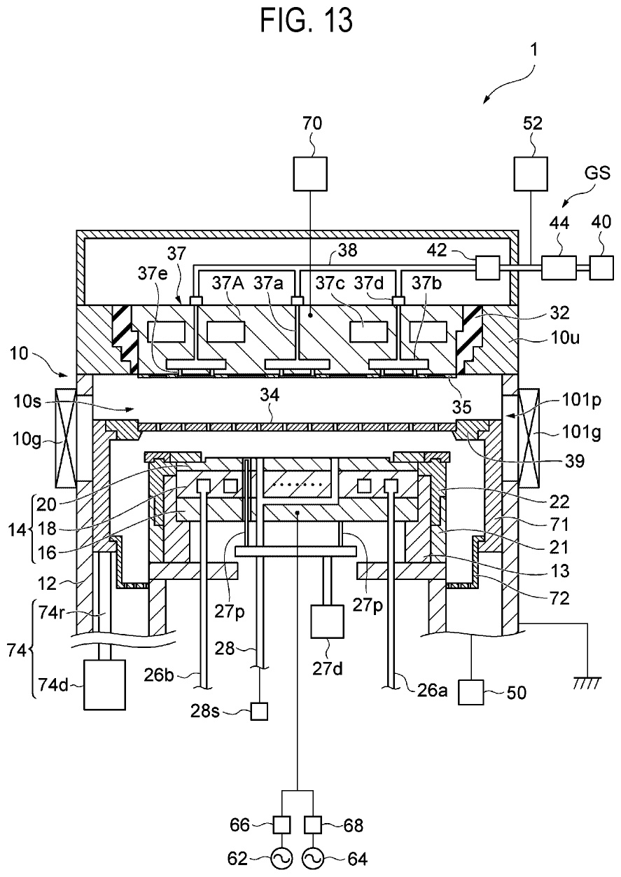

Thereafter, as illustrated in FIG. 13, the annular member 39 and the shutter 71 are moved upward by the shutter drive 74 to receive the ceiling plate 34 from the lifter pins 27p. The shutter drive 74 is controlled by the controller MC.

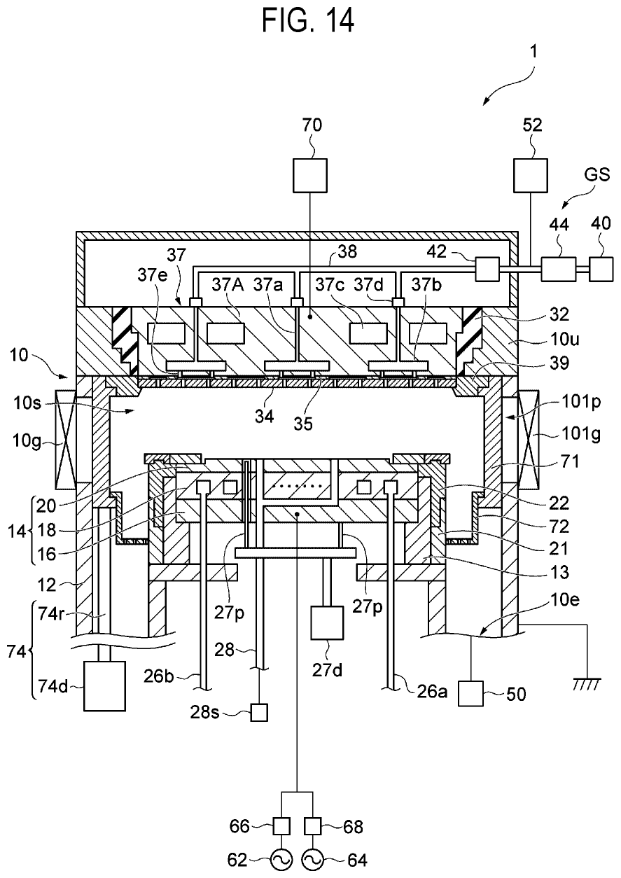

Then, as illustrated in FIG. 14, the annular member 39 and the shutter 71 are moved upward by the shutter drive 74 to move the ceiling plate 34 to a region immediately below the electrostatic adsorber 35. The shutter drive 74 is controlled by the controller MC.

In Method MT, subsequently, step STc is performed. In step STc, the ceiling plate 34 is held by the electrostatic adsorber 35. In step STc, one or more power supplies (e.g., the power supplies 351p and 352p) apply voltages (DC voltages or AC voltages) to the one or more electrodes 35b (e.g., the first electrode 351b and the second electrode 352b) of the electrostatic adsorber 35. The one or more power supplies are controlled by the controller MC.

As described above, the ceiling plate 34 can be replaced automatically and easily without bringing the internal space 10s in communication with the atmospheric space outside the chamber 10.

In one embodiment, the plasma processing system PS may further include a pressure regulator. The pressure regulator is configured to set a pressure in a gap between the ceiling plate 34 and the support 37 (electrostatic adsorber 35) to be lower than a pressure in a space between the ceiling plate 34 and the substrate support 14 when the ceiling plate 34 is held by the electrostatic adsorber 35. The pressure regulator may be the heat transfer gas supply mechanism 28s. The heat transfer gas supply mechanism 28s supplies a heat transfer gas to the space between the ceiling plate 34 and the substrate support 14. Thus, the pressure in the gap between the ceiling plate 34 and the support 37 (electrostatic adsorber 35) becomes to be lower than the pressure in the space between the ceiling plate 34 and the substrate support 14.

Alternatively, the pressure regulator may be an exhaust device 52. The exhaust device 52 includes a depressurizing pump connected to the gas supply pipe 38. The exhaust device 52 reduces the pressure in the gap between the ceiling plate 34 and the support 37 (electrostatic adsorber 35) to be lower than the pressure in the space between the ceiling plate 34 and the substrate support 14. In addition, instead of the exhaust device 52, the exhaust device 50 may be connected to the gas supply pipe 38. In this case, the pressure in the gap between the ceiling plate 34 and the support 37 (electrostatic adsorber 35) can be reduced by using the exhaust device 50.

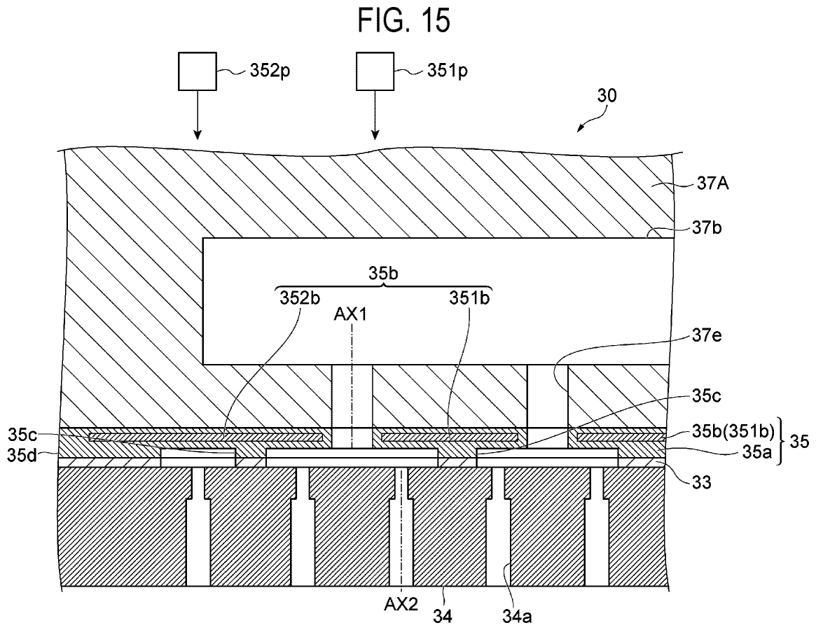

Hereinafter, reference will be made to FIG. 15. FIG. 15 is a cross-sectional view of an upper electrode according to another exemplary embodiment. The upper electrode illustrated in FIG. 15 further includes a resin sheet 33 disposed between the ceiling plate 34 and the electrostatic adsorber 35. The resin sheet 33 is sandwiched between the ceiling plate 34 and each of the protrusions 35c of the electrostatic adsorber 35. The resin sheet 33 enhances adhesion between the ceiling plate 34 and the electrostatic adsorber 35. In addition, the resin sheet 33 may be transferred and replaced together with the ceiling plate 34 by the arm.

While various exemplary embodiments have been described above, various additions, omissions, substitutions, and modifications may be made without being limited to the exemplary embodiments described above. Further, elements from different embodiments may be combined to form other embodiments.

For example, in the plasma processing system PS, the arm (arm ARM or arm AEX) may move the ceiling plate 34, which is transferred into the chamber 10, to the region immediately below the support 37 (electrostatic adsorber 35). Alternatively, the lifter pins 27p may move the ceiling plate 34 to the region immediately below the support 37 (electrostatic adsorber 35).

Further, the ceiling plate 34 may be held by a mechanical clamp of the support 37, instead of the electrostatic adsorber 35.

Here, various exemplary embodiments included in the present disclosure are described in the following [E1] to [E18].
[E1] A plasma processing system comprising:
   a capacitively coupled plasma processing apparatus that includes:
      a chamber having a wall defining an internal space and providing a passage;
      a substrate support provided inside the chamber;
      a ceiling plate having conductivity and provided above the substrate support; and
      a ceiling plate support having an electrostatic adsorber, the ceiling plate being disposed below the ceiling plate support; and
   a transfer device having an arm configured to be capable of entering the internal space via the passage,
   wherein the ceiling plate is transferred to the internal space by the arm and is held by the electrostatic adsorber.

In an embodiment of E1, the electrostatic adsorber of the ceiling plate support holds the ceiling plate by electrostatic attraction. Thus, the ceiling plate is detachable from the electrostatic adsorber. Further, the ceiling plate is loaded into the chamber by the arm, and is held by the electrostatic adsorber of the ceiling plate support by electrostatic attraction. Therefore, the ceiling plate can be replaced easily.
[E2] The plasma processing system of E1, further comprising a lifter configured to lift up the ceiling plate, which is transferred by the arm, to immediately below the ceiling plate support.
[E3] The plasma processing system of E2, wherein the lifter includes:
   a shutter having a cylindrical shape and provided inside the chamber to open and close the passage;
   a shutter drive configured to move the shutter up and down; and
   an annular member supported by the shutter and having an inner edge that supports the ceiling plate, and
   wherein the shutter and the annular member are provided radially outward of the substrate support.
[E4] The plasma processing system of E3, wherein the inner edge provides a stepped surface, and
   wherein the stepped surface provides a bottom surface, on which a peripheral edge of the ceiling plate is placed, and an inner peripheral surface facing an end surface of the ceiling plate.
[E5] The plasma processing system of E4, wherein a portion of the inner edge including the stepped surface is made of an insulating material.
[E6] The plasma processing system of any one of E3 to E5, wherein the annular member is made of a same material as the ceiling plate.
[E7] The plasma processing system of E6, wherein the annular member is made of silicon.
[E8] The plasma processing system of any one of E3 to E7, further comprising:
   lifter pins configured to be capable of protruding upward from an upper surface of the substrate support and retracting downward from the upper surface of the substrate support; and
   a pin drive configured to move the lifter pins up and down,
   wherein the pin drive moves the lifter pins upward to receive the ceiling plate transferred by the arm, and
   wherein the shutter drive moves the annular member and the shutter upward after the arm is retracted from the internal space, such that the annular member receives the ceiling plate from the lifter pins.
[E9] The plasma processing system of E2, wherein the lifter includes:
   lifter pins configured to be capable of protruding upward from an upper surface of the substrate support and retracting downward from the upper surface of the substrate support; and
   a pin drive configured to move the lifter pins, on which the ceiling plate is supported, up and down.
[E10] The plasma processing system of E8 or E9, wherein the lifter pins are configured to move a substrate or an edge ring, which is placed on the substrate support, up and down over the substrate support.
[E11] The plasma processing system of any one of E1 to E10, wherein the transfer device is a transfer module, which includes a transfer chamber providing a depressurizable transfer space and a transfer robot including the arm and is configured to transfer the substrate to the internal space, or an exchange station different from the transfer module.
[E12] The plasma processing system of any one of E1 to E11, further comprising a pressure regulator configured to set a pressure in a gap between the ceiling plate and the ceiling plate support to be lower than a pressure in a space between the ceiling plate and the substrate support.
[E13] The plasma processing system of E12, wherein the pressure regulator includes an exhaust device configured to reduce the pressure in the gap between the ceiling plate and the ceiling plate support.
[E14] The plasma processing system of any one of E1 to E12, further comprising a resin sheet disposed between the ceiling plate and the electrostatic adsorber.
[E15] The plasma processing system of any one of E1 to E14, further comprising a controller configured to control the transfer device.
[E16] The plasma processing system of E8, further comprising a controller configured to control the transfer device, the pin drive, and the shutter drive.
[E17] The plasma processing system of E15 or E16, wherein the controller is configured to replace the ceiling plate with another ceiling plate when an accumulated exposure time of the ceiling plate to plasma generated in the chamber or a consumption amount of the ceiling plate meets a predetermined criterion.
[E18] A maintenance method for the plasma processing system according to any one of E1 to E17, the maintenance method comprising:
   transferring the ceiling plate into the chamber using the arm; and
   holding the ceiling plate by the electrostatic adsorber.

According to the present disclosure, it is possible to easily replace an upper electrode plate of a capacitively coupled plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing system comprising:
a plasma processing apparatus that includes:
a plasma processing chamber;
a substrate support disposed inside the plasma processing chamber and having a lower electrode;
an upper electrode assembly disposed above the substrate support, and having an electrode support and a replaceable upper electrode plate disposed below the electrode support; and
a lifter configured to move the replaceable upper electrode plate vertically between an upper position and a lower position inside the plasma processing chamber, and configured to fix the replaceable upper electrode plate to the electrode support when the replaceable upper electrode plate is in the upper position; and
a transfer device that includes:
a transfer chamber; and
a transfer robot disposed inside the transfer chamber, and configured to transfer the replaceable upper electrode plate between the lower position inside the plasma processing chamber and the transfer chamber.

2. The plasma processing system of claim 1, wherein the lifter includes:
a cylindrical wall structure disposed between an inner wall of the plasma processing chamber and the substrate support, and configured to support the replaceable upper electrode plate; and
an actuator configured to move the cylindrical wall structure vertically.

3. The plasma processing system of claim 2, wherein the cylindrical wall structure includes:
a cylindrical member; and
an annular member extending inward from the cylindrical member and configured to support the replaceable upper electrode plate.

4. The plasma processing system of claim 3, wherein the annular member has an inner peripheral stepped surface, and the replaceable upper electrode plate is supported by the inner peripheral stepped surface.

5. The plasma processing system of claim 4, wherein the cylindrical wall structure further includes an insulator disposed on the inner peripheral stepped surface.

6. The plasma processing system of claim 3, wherein the annular member is made of a same material as the replaceable upper electrode plate.

7. The plasma processing system of claim 3, wherein the replaceable upper electrode plate and the annular member are made of silicon.

8. The plasma processing system of claim 1, wherein the substrate support includes lifter pins configured to support the replaceable upper electrode plate in the lower position.

9. The plasma processing system of claim 8, wherein the lifter pins are configured to support a substrate at a location above the substrate support.

10. The plasma processing system of claim 8, wherein the lifter pins are configured to support an edge ring at a location above the substrate support.

11. The plasma processing system of claim 1, wherein the transfer device is a substrate transfer module configured to transfer a substrate under a vacuum environment.

12. The plasma processing system of claim 1, further comprising a pressure regulator configured to set a pressure in a gap between the replaceable upper electrode plate and the electrode support to be lower than a pressure in a space between the replaceable upper electrode plate and the substrate support.

13. The plasma processing system of claim 12, wherein the pressure regulator includes an exhaust device configured to reduce the pressure in the gap between the replaceable upper electrode plate and the electrode support.

14. The plasma processing system of claim 1, wherein the electrode support includes:
a support member; and
an electrostatic adsorption layer attached to the support member and configured to electrostatically adsorb the replaceable upper electrode plate.

15. The plasma processing system of claim 14, wherein the electrode support further includes a resin sheet disposed between the replaceable upper electrode plate and the electrostatic adsorption layer.

16. The plasma processing system of claim 1, further comprising a controller configured to control the lifter and the transfer robot to perform:
moving the replaceable upper electrode plate from the upper position to the lower position; and
transferring the replaceable upper electrode plate from the lower position inside the plasma processing chamber to the transfer chamber.

17. The plasma processing system of claim 16, wherein the controller is further configured to control the lifter and the transfer robot to perform:
transferring a replaceable upper electrode plate before use from the transfer chamber to the lower position inside the plasma processing chamber; and
moving the replaceable upper electrode plate before use from the lower position to the upper position.

18. A plasma processing apparatus comprising:
a plasma processing chamber;
a substrate support disposed inside the plasma processing chamber and having a lower electrode;
an upper electrode assembly disposed above the substrate support, and having an electrode support and a replaceable upper electrode plate disposed below the electrode support; and
a lifter configured to move the replaceable upper electrode plate vertically between an upper position and a lower position inside the plasma processing chamber, and configured to fix the replaceable upper electrode plate to the electrode support when the replaceable upper electrode plate is in the upper position.

19. The plasma processing apparatus of claim 18, wherein the lifter includes:
a cylindrical wall structure disposed between an inner wall of the plasma processing chamber and the substrate support, and configured to support the replaceable upper electrode plate; and
an actuator configured to move the cylindrical wall structure vertically.

20. A plasma processing system comprising:
a capacitively coupled plasma processing apparatus that includes:
a chamber having a wall defining an internal space and providing a passage;
a substrate support provided inside the chamber;
a ceiling plate having conductivity and provided above the substrate support; and
a ceiling plate support having an electrostatic adsorber, the ceiling plate being disposed below the ceiling plate support; and
a transfer device having an arm configured to be capable of entering the internal space via the passage,
wherein the ceiling plate is transferred to the internal space by the arm and is held by the electrostatic adsorber.
